(19) United States
(12) Patent Application Publication
(10) Pub. No.: US 2014/0085852 A1
(43) Pub. Date: Mar. 27, 2014

(54) MULTILAYER CERAMIC ELECTRONIC COMPONENT

(71) Applicant: SAMSUNG ELECTRO-MECHANICS CO., LTD., Suwon (KR)

(72) Inventors: Kyu Sik Park, Suwon (KR); Jae Yeol Choi, Suwon (KR); Young Sook Lee, Suwon (KR); Myung Jun Park, Suwon (KR)

(73) Assignee: SAMSUNG ELECTRO-MECHANICS CO., LTD., Suwon (KR)

(21) Appl. No.: 13/840,904

(22) Filed: Mar. 15, 2013

(30) Foreign Application Priority Data
Sep. 27, 2012 (KR) 10-2012-0107928

(51) Int. Cl. H05K 1/02

(52) U.S. Cl. CPC H05K 1/0216
USPC 361/782

(57) ABSTRACT

There is provided a multilayer ceramic electronic component including: a ceramic body in which a plurality of dielectric layers are stacked; a plurality of first and second internal electrodes formed on at least one surfaces of the dielectric layers and alternately exposed through both end surfaces of the ceramic body in a length direction of the ceramic body; a first acoustic noise absorption layer formed on one surface of the ceramic body in a stacking direction of the dielectric layers and having a thickness of 3 μm to 500 μm; first and second external electrodes formed on both end surfaces of the ceramic body and electrically connected to exposed portions of the first and second internal electrodes; and a printed circuit board having the first and second external electrodes mounted thereon while facing the first acoustic noise absorption layer.

### CROSS-REFERENCE TO RELATED APPLICATIONS

This application claims the priority of Korean Patent Application No. 10-2012-0107928 filed on Sep. 27, 2012, in the Korean Intellectual Property Office, the disclosure of which is incorporated herein by reference.

### BACKGROUND OF THE INVENTION

1. Field of the Invention

The present invention relates to a multilayer ceramic electronic component.

2. Description of the Related Art

Provided as representative electronic components using a ceramic material are a capacitor, an inductor, a piezoelectric element, a varistor, a thermistor, and the like.

Among ceramic electronic components, a multilayer ceramic capacitor (MLCC) has a small size, is able to secure high capacity, and has ease of mountability.

A multilayer ceramic capacitor, a chip-type condenser, is installed in circuit boards of various electronic products including a display device such as a liquid crystal display (LCD), a plasma display panel (PDP), or the like, a computer, a personal digital assistant (PDA), a cellular phone, and the like, in order to charge or discharge electricity therein.

Due to the recent trend in which display devices are relatively large, computer central processing units (CPUs) have been increased in speed, and the like, heat generation in electronic devices has become a serious issue.

Therefore, it is necessary for multilayer ceramic capacitors to secure a stable capacity and reliability at high temperatures so that an integrated circuit (IC) installed in the electronic device can be stably operated.

In addition, as electronic products have recently become smaller, demand for a multilayer ceramic capacitor having a small size and high capacitance has increased.

For this reason, a multilayer ceramic capacitor in which dielectric layers and internal electrodes are formed to be relatively thin for ultra-miniaturization of the product, and a large number of dielectric layers are stacked to allow for ultra-high capacitance therein has been manufactured.

In order to satisfy the requirements for ultra-miniaturization and ultra-high capacitance in multilayer ceramic capacitors, a green sheet to be formed as the dielectric layer may be relatively thin, while respective thicknesses of upper and lower cover portions of a multilayer body in which the plurality of green sheets are stacked maybe decreased, or a width of a margin portion on the green sheet may be reduced by as much as possible to thereby allow an internal electrode to be formed to be as large as possible.

Here, in the case in which thicknesses of margin portions and upper and lower cover portions of green sheets are excessively reduced, acoustic noise may be generated at the time of mounting the multilayer ceramic electronic component on a printed circuit board.

The acoustic noise is transferred to the printed circuit board through external electrodes, such that the entire printed circuit board serves as a sound reflecting surface to thereby reflect an acoustic sound as a noise.

Since the acoustic sound, which corresponds to an acoustic sound having an audible frequency, may be within a range that may be unpleasant to users, it is necessary to reduce noise, and in particular, the reduction of noise corresponding to acoustic sounds becomes an essential factor in a mobile device.

### SUMMARY OF THE INVENTION

An aspect of the present invention provides a multilayer ceramic electronic component capable of preventing an acoustic sound generated at the time of being mounted on a printed circuit board and noise resulting therefrom, while implementing a product having an ultra-small size and ultra-high capacitance by decreasing margin portions and thicknesses of cover portions of dielectric layers as much as possible.

According to an aspect of the present invention, there is provided a multilayer ceramic electronic component including: a ceramic body in which a plurality of dielectric layers are stacked; a plurality of first and second internal electrodes formed on at least one surfaces of the dielectric layers and alternately exposed through both end surfaces of the ceramic body in a length direction of the ceramic body; a first acoustic noise absorption layer formed on one surface of the ceramic body in a stacking direction of the dielectric layers and having a thickness of 3 μm to 500 μm; first and second external electrodes formed on both end surfaces of the ceramic body and electrically connected to exposed portions of the first and second internal electrodes; and a printed circuit board having the first and second external electrodes mounted thereon while facing the first acoustic noise absorption layer.

The first acoustic noise absorption layer may be formed of a non-conductive polymer.

The ceramic body may have a second acoustic noise absorption layer formed on the other surface thereof and facing the first acoustic noise absorption layer.

The second acoustic noise absorption layer may have a thickness of 3 μm to 500 μm.

The second acoustic noise absorption layer may be formed of a non-conductive polymer.

According to another aspect of the present invention, there is provided a multilayer ceramic electronic component including:

a ceramic body in which a plurality of dielectric layers are stacked; a plurality of first and second internal electrodes formed on at least one surfaces of the dielectric layers and alternately exposed through both end surfaces of the ceramic body in a length direction of the ceramic body; a first acoustic noise absorption layer formed on one surface of the ceramic body in a direction perpendicular to a stacking direction of the dielectric layers and having a thickness of 3 μm to 500 μm; first and second external electrodes formed on both end surfaces of the ceramic body and electrically connected to exposed portions of the first and second internal electrodes; and a printed circuit board having the first and second external electrodes mounted thereon while facing the first acoustic noise absorption layer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view schematically showing a structure of a multilayer ceramic electronic component according to an embodiment of the present invention;

FIG. 2 is a perspective view showing a structure in which a ceramic body, and first and second acoustic noise absorption layers are formed according to the embodiment of the present invention;

FIG. 3 is a graph showing a magnitude of acoustic noise according to a thickness of a non-conductive polymer applied to the acoustic noise absorption layer;

FIG. 4 is a cross-sectional view schematically showing a state in which the acoustic noise is generated in the multilayer ceramic electronic component of FIG. 1; and

FIG. 5 is a perspective view showing a structure in which a ceramic body, and first and second acoustic noise absorption layers are formed, according to another embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of components may be exaggerated for clarity, and the same reference numerals will be used throughout to designate the same or like components.

The present invention relates to a multilayer ceramic electronic component, wherein the multilayer ceramic electronic component according to an embodiment of the present invention includes a multilayer ceramic capacitor, an inductor, a piezoelectric element, a varistor, a chip resistor, a thermistor, and the like. Hereinafter, the multilayer ceramic capacitor will be described as an example of multilayer ceramic electronic products.

In addition, for convenience of description, in the embodiment of the present invention, surfaces of a ceramic body in a direction in which first and second external electrodes are formed refer to both end surfaces, surfaces thereof vertically intersecting with the both end surfaces refer to both side surfaces, and surfaces thereof in a thickness direction refer to upper and lower surfaces.

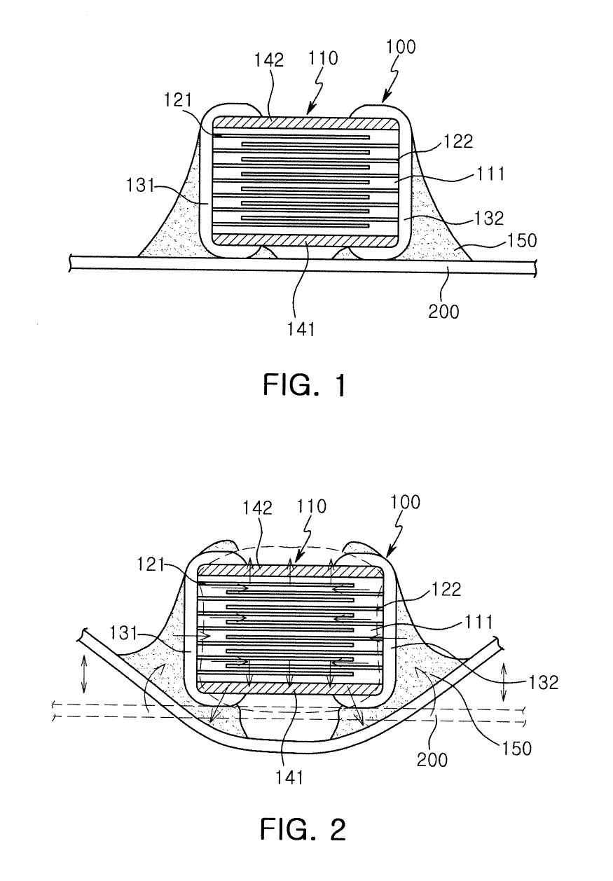

Referring to FIGS. 1 and 2, a multilayer ceramic capacitor 100 according to the embodiment of the present invention may include: a ceramic body 110 in which a plurality of dielectric layers 111 are stacked; a plurality of first and second internal electrodes 121 and 122 formed on at least one surfaces of the dielectric layers 111 and alternately exposed through both end surfaces of the ceramic body 110 in a length direction of the ceramic body 111; a first acoustic noise absorption layer 141 formed on a lower surface of the ceramic body 110 in the stacking direction of the dielectric layer 111; and first and second external electrodes 131 and 132 formed on both end surfaces of the ceramic body 110 and electrically connected to exposed portions of the first and second internal electrodes 121 and 122.

The ceramic body 110 may be formed by stacking the plurality of dielectric layers 111.

Here, the plurality of dielectric layers 111 configuring the ceramic body 110 may be integrated with each other so that a boundary between adjacent dielectric layers 111 in a sintered state may not be readily apparent.

In addition, the shape of the ceramic body 110 is not particularly limited, but the ceramic body 110 may generally have a rectangular parallelepiped shape.

Further, the ceramic body 110 is not particularly limited in terms of dimensions thereof. However, for example, the ceramic body 110 may have a 0603 size (0.6 mm×0.3 mm), or the like, to thereby manufacture the multilayer ceramic capacitor 100 having a capacitance of 1.0 μF or higher.

The dielectric layers 111 configuring the ceramic body 110 may include a ceramic powder, for example, a BaTiO₃-based ceramic powder, or the like.

Examples of the BaTiO₃-based ceramic powder may include (Ba₁₋ₓCaₓ)TiO₃, Ba(Ti_{1-y}Ca_{y})O₃, (Ba₁₋ₓCaₓ) (Ti_{1-y}Zr_{y})O₃, or Ba(Ti_{1-y}Zr_{y})O₃ , or the like, in which Ca, Zr, or the like, is partially combined with BaTiO₃, without being limited thereto.

The ceramic powder may have an average particle size of 0.8 μm or less, and more preferably, 0.05 to 0.5 μm, but the present invention is not limited thereto.

In addition, if needed, the dielectric layers 111 may further contain at least one material selected from a transition metal oxide, a carbide, a rare-earth element, Mg, and Al, together with the ceramic powder.

Further, a thickness of the dielectric layer 111 may be arbitrarily changed according to a capacity design of the multilayer ceramic capacitor 100.

The first and second internal electrodes 121 and 122 may be formed of a conductive paste containing a conductive metal.

Here, the conductive metal may be Ni, Cu, Pd or an alloy thereof, but the present invention is not limited thereto.

The internal electrodes 121 and 122 maybe formed by printing the conductive paste on the ceramic green sheets forming dielectric layers using a printing method, such as screen printing or gravure printing. Then, the ceramic green sheets on which the internal electrodes are printed are stacked alternately with each other, followed by sintering, thereby forming the ceramic body 110.

As such, capacitance maybe formed due to an area in which the first and second internal electrodes 121 and 122 are overlapped.

When the first and second internal electrodes 121 and 122 are formed on the dielectric layers 111 as described above, a predetermined margin portion may be left between edges of the dielectric layers 111 and those of the first and second internal electrodes 121 and 122, in order to prevent moisture, a plating solution, and the like from permeating into the ceramic body and prevent a short circuit.

The margin portion may be formed to be as small as possible to facilitate miniaturization of the product; however, the formation of a margin portion having an excessively small size may be a cause of acoustic noise.

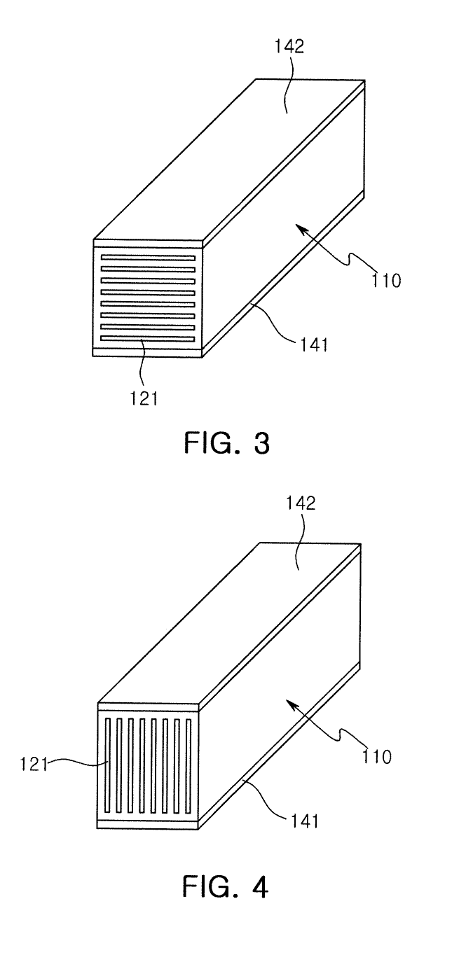

Table 1 and FIG. 3 show a change in acoustic noise in accordance with a thickness of the first acoustic noise absorption layer 141, respectively.

TABLE 1

Acoustic Noise(dB)
Fillet Thickness

| Classification | 200 μm | 300 μm |
|---|---|---|
| Sample 1 | 25 | 31 |
| Cover 50 μm | | |
| Sample 2 | 30 | 34 |
| 2 μm | | |
| Sample 3 | 26 | 29 |
| 3 μm | | |
| Sample 4 | 19 | 24 |
| 50 μm | | |
| Sample 5 | 11 | 21 |
| 150 μm | | |
| Sample 6 | 10 | 19 |
| 300 μm | | |
| Sample 7 | 6 | 8 |
| 500 μm | | |

Here, acoustic noise was measured by using fillets of 200 μm and 300 μm, respectively.

In sample 1, the first acoustic noise absorption layer was formed of the same material as the ceramic body 110, and in samples 2 to 7, the first acoustic noise absorption layers were formed of a non-conductive polymer.

Referring to Table 1 and FIG. 3, it maybe appreciated that in the case of using the first acoustic noise absorption layer, a relatively small amount of noise of 40 db or less was measured, and in the case of samples 3 to 7 using the non-conductive polymer, the noise was reduced further than in the case of sample 1 using the ceramic material.

In addition, in sample 2, the thickness of the first acoustic noise absorption layer was excessively thin, leading to a higher level of noise than that of sample 1 using the same material as the ceramic body 110; however, in sample 3, the noise was generated at a level similar to that of sample 1. Accordingly, it may be appreciated that a preferable thickness of the first acoustic noise absorption layer may be at least 3 μm to 500 μm.

Therefore, the thickness of the first acoustic noise absorption layer 141 may be 3 μm to 500 μm, and may be in a range allowing the fillet to be formed at the time of being mounted on a printed circuit board 200.

In addition, the first acoustic noise absorption layer 141 may be formed of a first non-conductive polymer. The non-conductive polymer may absorb and buffer the acoustic noise generated at the time of applying voltage, to thereby further reduce the noise.

A second acoustic noise absorption layer 142 may be formed on an upper surface of the ceramic body 100 so as to face the first acoustic noise absorption layer 141. The second acoustic noise absorption layer 142 may be formed to be symmetrical with regard to the first acoustic noise absorption layer 141, and if necessary, the present invention may be variously changed, for example, the second acoustic noise absorption layer 142 may be formed to be asymmetrical with regard to the first acoustic noise absorption layer 141.

That is, a thickness of the second acoustic noise absorption layer 142 may be 3 μm to 500 μm, similar to that of the first acoustic noise absorption layer 141, and may be applied in a range allowing the fillet to be formed at the time of being mounted on the printed circuit board 200. In addition, the second acoustic noise absorption layer 142 may also be formed of a non-conductive polymer, like the first acoustic noise absorption layer 141.

The first and second acoustic noise absorption layers 141 and 142 may be formed on the upper and lower surfaces of the ceramic body 110, respectively, to serve as dielectric cover layers.

The first and second external electrodes 131 and 132 may be formed of a material having excellent conductivity, and may be electrically connected to the first and second internal electrodes 121 and 122 formed in the multilayer ceramic capacitor 100, or other various patterns and the printed circuit board 200.

The first and second external electrodes 131 and 132 may be formed of a material having excellent conductivity such as nickel (Ni), silver (Ag), or palladium (Pd); however, the present invention is not limited thereto.

The printed circuit board 200 may have a circuit pattern (not shown) on an upper surface thereof, and the multilayer ceramic capacitor 100 may be mounted on the printed circuit board 200.

The first and second external electrodes 131 and 132 of the multilayer ceramic capacitor 100 may electrically contact the circuit pattern of the printed circuit board 200, and the multilayer ceramic capacitor 100 may be adhered to and mounted on the printed circuit board 200 by soldering lower surfaces and side surfaces of the first and second external electrodes 131 and 132 of the multilayer ceramic capacitor 100 to the printed circuit board 200 by a solder 150.

Here, in order to obtain an effect of reducing the acoustic noise, one of the first acoustic noise absorption layer 141 and the second acoustic noise absorption layer 142 is required to be positioned above the printed circuit board 200.

As shown in FIG. 4, when an electric field is applied to the multilayer ceramic capacitor 100 configured as described above, stress is generated in X, Y, and Z directions of the ceramic body 110, and the acoustic noise is generated by the stress.

A multilayer ceramic capacitor according to the related art is formed by applying BaTiO₃, the same material as that of a ceramic body, to margin portions and upper and lower cover portions of the ceramic body, other than portions thereof in which internal electrodes for implementing electrical characteristics are formed.

The margin portions and the cover portions formed of such a ceramic material do not absorb acoustic noise generated at the time of applying an electric field, but rather serve to transmit the generated acoustic noise to the printed circuit board through external electrodes, such that the acoustic noise and a magnitude of the noise may be problematically large.

However, according to the embodiment of the present invention, since the acoustic noise absorption layer is formed on one surface of the ceramic body 110 corresponding to a mounting surface of the printed circuit board 200, the acoustic noise generated at the time of applying the voltage may be absorbed and buffered to reduce the noise by as much as possible.

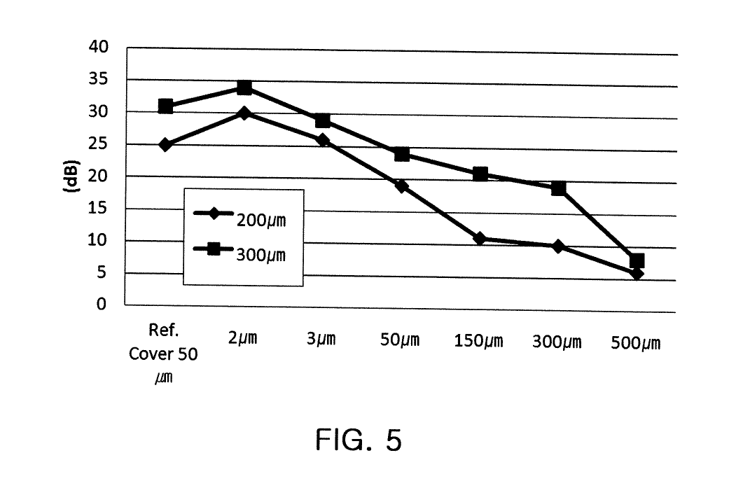

Meanwhile, referring to FIG. 5, in the multilayer ceramic capacitor according to another embodiment of the present invention, the first acoustic noise absorption layer 141 may be formed on one surface of the ceramic body 110 in a direction perpendicular to a stacking direction of the dielectric layers 111.

That is, in the case of the previous embodiment, the multilayer ceramic capacitor 100 is mounted on the printed circuit board 200 in a direction parallel to the stacking direction of the first and second internal electrodes 121 and 122, that is, the first and second acoustic noise absorption layers 141 and 142 are formed on the upper and lower cover portions of the ceramic body 110.

In addition, in the case of another embodiment, the multilayer ceramic capacitor 100 is mounted on the printed circuit board 200 in a direction perpendicular to the stacking direction of the first and second internal electrodes 121 and 122, that is, the first and second acoustic noise absorption layers 141 and 142 are formed on both margin portions of the ceramic body 110.

Hereinafter, a method of manufacturing a multilayer ceramic capacitor according to an embodiment of the present invention will be described.

A plurality of ceramic green sheets are prepared.

The individual ceramic green sheets, forming the dielectric layers 111 of the ceramic body 110, may be manufactured by mixing a ceramic powder, a polymer, and a solvent to prepare a slurry, and forming a sheet using the slurry, the sheet having a thickness of several μm, for example, 1.8 μm, by a doctor blade, or the like.

Then, a conductive paste may be printed on at least one surface of each ceramic green sheet to have a predetermined thickness, for example, 0.2 to 1.0 μm, to form first and second internal electrode films.

Here, the conductive paste may be printed while allowing margin portions to be formed in the ceramic green sheets along edge portions thereof so as to have a predetermined width from the first and second internal electrode films.

Then, the ceramic green sheets in which the first and second internal electrode films are formed may be partially removed with respect to surfaces on which the first and second internal electrode films are to be exposed to thereby form grooves.

Next, the plurality of ceramic green sheets having the first and second internal electrode films formed thereon are stacked and pressurized in a stacking direction, thereby compressing the plurality of ceramic green sheets and the conductive paste formed on the ceramic green sheets to configure a multilayer body having the first and second internal electrodes 121 and 122 formed therein.

Then, a paste formed of a non-conductive polymer is applied to a lower surface of the multilayer body, to thereby form the first acoustic noise absorption layer 141 having a thickness of 3 μm to 500 μm.

Here, if needed, the second acoustic noise absorption layer 142 may be formed on an upper surface of the multilayer body so as to face the first acoustic noise absorption layer 141. The second acoustic noise absorption layer 142 may be formed by applying a paste formed of a non-conductive polymer to have a thickness of 3 μm to 500 μm, similar to the first acoustic noise absorption layer 141.

Then, the multilayer body is cut per area corresponding to each multilayer ceramic capacitor to be produced as a chip, and sintered at a high temperature to thereby form the ceramic body 110.

Next, the first and second external electrodes 131 and 132 may be formed by covering both end surfaces of the ceramic body 110 using a conductive material. The first and second external electrodes 131 and 132 may be electrically connected to the first and second internal electrodes 121 and 122, respectively.

Here, if needed, surfaces of the first and second external electrodes 131 and 132 maybe subjected to a plating treatment using nickel, tin, or the like.

Then, the multilayer ceramic capacitor 100 is mounted on the printed circuit board 200 on which the circuit pattern is formed, while allowing one of the first and the second acoustic noise absorption layers 141 and 142 to be adjacent to the printed circuit board 200.

Here, the first and second external electrodes 131 and 132 of the multilayer ceramic capacitor 100 may be electrically contacted to the circuit pattern of the printed circuit board 200, and the multilayer ceramic capacitor 100 may be mounted by soldering lower surfaces and side surfaces of the first and second external electrodes 131 and 132.

As set forth above, in a multilayer ceramic electronic component according to embodiments of the present invention, an acoustic noise absorption layer formed on a ceramic body is mounted to be adjacent to a mounting surface of a printed circuit board, to thereby absorb an acoustic noise generated at the time of applying voltage to a product, whereby the noise may be reduced.

While the present invention has been shown and described in connection with the embodiments, it will be apparent to those skilled in the art that modifications and variations can be made without departing from the spirit and scope of the invention as defined by the appended claims.

What is claimed is:

1. A multilayer ceramic electronic component comprising:
a ceramic body in which a plurality of dielectric layers are stacked;
a plurality of first and second internal electrodes formed on at least one surfaces of the dielectric layers and alternately exposed through both end surfaces of the ceramic body in a length direction of the ceramic body;
a first acoustic noise absorption layer formed on one surface of the ceramic body in a stacking direction of the dielectric layers and having a thickness of 3 μm to 500 μm;
first and second external electrodes formed on both end surfaces of the ceramic body and electrically connected to exposed portions of the first and second internal electrodes; and
a printed circuit board having the first and second external electrodes mounted thereon while facing the first acoustic noise absorption layer.

2. The multilayer ceramic electronic component of claim 1, wherein the first acoustic noise absorption layer is formed of a non-conductive polymer.

3. The multilayer ceramic electronic component of claim 1, wherein the ceramic body has a second acoustic noise absorption layer formed on the other surface thereof and facing the first acoustic noise absorption layer.

4. The multilayer ceramic electronic component of claim 3, wherein the second acoustic noise absorption layer has a thickness of 3 μm to 500 μm.

5. The multilayer ceramic electronic component of claim 3, wherein the second acoustic noise absorption layer is formed of a non-conductive polymer.

6. A multilayer ceramic electronic component comprising:
a ceramic body in which a plurality of dielectric layers are stacked;
a plurality of first and second internal electrodes formed on at least one surfaces of the dielectric layers and alternately exposed through both end surfaces of the ceramic body in a length direction of the ceramic body;
a first acoustic noise absorption layer formed on one surface of the ceramic body in a direction perpendicular to a stacking direction of the dielectric layers and having a thickness of 3 μm to 500 μm;
first and second external electrodes formed on both end surfaces of the ceramic body and electrically connected to exposed portions of the first and second internal electrodes; and
a printed circuit board having the first and second external electrodes mounted thereon while facing the first acoustic noise absorption layer.

7. The multilayer ceramic electronic component of claim 6, wherein the first acoustic noise absorption layer is formed of a non-conductive polymer.

8. The multilayer ceramic electronic component of claim 6, wherein the ceramic body has a second acoustic noise absorption layer formed on the other surface thereof and facing the first acoustic noise absorption layer.

9. The multilayer ceramic electronic component of claim 8, wherein the second acoustic noise absorption layer has a thickness of 3 μm to 500 μm.

10. The multilayer ceramic electronic component of claim 8, wherein the second acoustic noise absorption layer is formed of a non-conductive polymer.
